(19) United States
(12) Patent Application Publication
(10) Pub. No.: US 2025/0023007 A1
(43) Pub. Date: Jan. 16, 2025

(54) LIGHT EMITTING DEVICE

(71) Applicant: LUMINUS (XIAMEN) CO., LTD, Fujian (CN)

(72) Inventors: Xiaoqiang ZENG, Fujian (CN); Jianfeng YANG, Fujian (CN); Shaohua HUANG, Fujian (CN)

(73) Assignee: LUMINUS (XIAMEN) CO., LTD, Fujian (CN)

(21) Appl. No.: 18/898,721

(22) Filed: Sep. 27, 2024

Related U.S. Application Data
(63) Continuation of application No. PCT/CN2023/070726, filed on Jan. 5, 2023.

(30) Foreign Application Priority Data
Mar. 28, 2022 (CN) 202210316575.9

(51) Int. Cl. H01L 33/62; H01L 25/075; H01L 33/08

(52) U.S. Cl. CPC H01L 33/62; H01L 25/0753; H01L 33/08

(57) ABSTRACT

The disclosure provides a light emitting device including a plurality of light emitting units and a plurality of wire bonding layers, each light emitting unit includes a first electrode and second electrode, the first electrode and the second electrode are spaced apart from each other, and the electrical properties of the first electrode and the second electrode are different. Multiple light emitting units are electrically connected to each other through multiple wire bonding layers, in which the spacing between two adjacent light emitting units is 0.5 μm to 50 μm, and the length of each wire bonding layer projected onto the light emitting unit is greater than or equal to 150 μm.

### CROSS-REFERENCE TO RELATED APPLICATION

This application is a continuation of international application of PCT application serial no. PCT/CN2023/070726, filed on Jan. 5, 2023, which claims the priority benefit of China application no. 202210316575.9, filed on Mar. 28, 2022. The entirety of each of the above-mentioned patent applications is hereby incorporated by reference herein and made a part of this specification.

### BACKGROUND

### Technical Field

The disclosure relates to the field of semiconductor manufacturing technology, and in particular to a light emitting device.

### Description of Related Art

Light Emitting Diode (LED) is a semiconductor light emitting element, usually made of semiconductors such as GaN, GaAs, GaP, and GaAsP, the core thereof is a PN junction with luminous properties. Under forward voltage, electrons are injected from the N region into the P region, and holes are injected from the P region into the N region. Some of the charge carriers recombine with majority carriers to emit light. LED has advantages such as high luminous intensity, high efficiency, small size, long service life, and is considered to be one of the most promising light sources currently.

In order to adapt to the application end power supply, high voltage medium and low current drive packaging platform came into being. More and more LED products divide the original single chip into multiple smaller chips, and then connect the multiple smaller chips in series to make LED products have better optoelectronic properties to meet the market demand for high optical power density as much as possible. However, when using multiple small chips in series, it is necessary to consider the safe wire bonding distance in the packaging process (safe wire bonding distance ≥150 μm), and thus the gap between the small chips cannot be reduced, and it is not possible to better meet the market demand for high optical power density of LED products.

A complete set of bonding wire includes the first bonding point, the second bonding point, and the wire bonding arc; the limitation of the safe wire bonding distance mainly comes from the wire bonding equipment of the packaging process. Specifically, the porcelain nozzle of the bonding wire cannot come into contact with the first bonding point that has already been made when making the second bonding point. The physical size of the porcelain nozzle and the size of the bonding point determine that the distance between the two bonding points cannot be reduced to 0. The safe wire bonding distance should at least be greater than the sum of the radius of the porcelain nozzle and the radii of the two bonding points. Therefore, in practice, the safe wire bonding distance needs to be ≥150 μm.

Therefore, how to reduce the gap between chips while ensuring the safe wire bonding distance has become a major technical problem that need to be solved urgently by technical personnel in this field.

### SUMMARY

The disclosure provides a light emitting device, which includes a plurality of light emitting units and a plurality of wire bonding layers.

Each light emitting unit includes a first electrode and a second electrode. The first electrode and the second electrode are spaced apart from each other. The electrical properties of the first electrode and the second electrode are different. The plurality of light emitting units are electrically connected to each other through the plurality of wire bonding layers. In the configuration, the spacing between two adjacent light emitting units is 0.5 μm to 50 μm, and a length of each wire bonding layer projected onto the light emitting unit is greater than or equal to 150 μm.

In an embodiment, the plurality of light emitting units are connected in series, viewing from above the light emitting device toward the plurality of light emitting units, each of the plurality of light emitting units has four sides, and the four sides are defined as a first long side, a first short side, a second long side, and a second short side sequentially in a surrounding direction; in which a first horizontal distance from the first electrode to the first short side is ⅛ to ½ of a length of the first long side, and a second horizontal distance from the second electrode to the second short side is 1/100 to 1/10 of the length of the first long side; or the second horizontal distance from the second electrode to the second short side is ⅛ to ½ of the length of the first long side, and the first horizontal distance from the first electrode to the first short side is 1/100 to 1/10 of the length of the first long side; or the first horizontal distance from the first electrode to the first short side is 1/16 to ⅛ of the length of the first long side, and the second horizontal distance from the second electrode to the second short side is 1/16 to ⅛ of the length of the first long side.

In an embodiment, the plurality of light emitting units are connected in parallel, viewing from above the light emitting device toward the plurality of light emitting units, each of the plurality of light emitting units has four sides, and the four sides are defined as a first long side, a first short side, a second long side, and a second short side sequentially in a surrounding direction; in which a first horizontal distance from the first electrode to the first short side is ⅛ to ½ of a length of the first long side, a fourth horizontal distance from the first electrode to the second short side is 1/100 to 1/10 of the length of the first long side, a second horizontal distance from the second electrode to the second short side is ⅛ to ½ of the length of the first long side, and a fifth horizontal distance from the second electrode to the first short side is 1/100 to 1/10 of the length of the first long side; or the first horizontal distance from the first electrode to the first short side is 1/100 to 1/10 of the length of the first long side, the fourth horizontal distance from the first electrode to the second short side is ⅛ to ½ of the length of the first long side, the second horizontal distance from the second electrode to the second short side is 1/100 to 1/10 of the length of the first long side, and the fifth horizontal distance from the second electrode to the first short side is ⅛ to ½ of the length of the first long side; or the first horizontal distance from the first electrode to the first short side is 1/16 to ⅛ of the length of the first long side, the fourth horizontal distance from the first electrode to the second short side is 1/16 to ⅛ of the length of the first long side, the second horizontal distance from the second electrode to the second short side is 1/16 to ⅛ of the length of the first long side, and the fifth horizontal distance from the second electrode to the first short side is 1/16 to ⅛ of the length of the first long side.

In an embodiment, there is a third horizontal distance between the first electrode and the second electrode of each of the plurality of light emitting units, and the third horizontal distance is 3/10 to ½ of the length of the first long side.

In an embodiment, a first vertical distance from the first electrode to the first long side is 3/20 to 3/10 of a length of a first short side, a second vertical distance from the second electrode to the first long side is 1/50 to 1/20 of the length of the first short side, and the first vertical distance is greater than the second vertical distance; or the first vertical distance from the first electrode to the first long side is 1/50 to 1/20 of the length of the first short side, the second vertical distance from the second electrode to the first long side is 3/20 to 3/10 of the length of the first short side, and the first vertical distance is less than the second vertical distance.

In an embodiment, each of the plurality of light emitting units further includes a substrate, the substrate has a first side and a second side opposite to each other, and the first electrode and the second electrode are located on the first side of the substrate.

In an embodiment, each of the plurality of light emitting units further includes an epitaxial structure, a groove, and an insulation layer, the epitaxial structure includes a first semiconductor layer, a light emitting layer, and a second semiconductor layer, the light emitting layer is located between the first semiconductor layer and the second semiconductor layer, the second semiconductor layer is closer to the substrate than the first semiconductor layer, the groove extends to the first semiconductor layer in a direction from a surface of the second semiconductor layer to the light emitting layer, the first electrode is electrically connected to the first semiconductor layer, the second electrode is electrically connected to the second semiconductor layer, and the insulation layer covers the groove and the epitaxial structure, so that the first electrode and the second electrode are electrically insulated from each other.

In an embodiment, each of the plurality of light emitting units further includes a first electrical connection layer and a second electrical connection layer, the first electrical connection layer is connected to the first semiconductor layer through the groove, the second electrical connection layer is connected to the second semiconductor layer, the first electrical connection layer and the second electrical connection layer each have an exposed area at a side away from the substrate, the first electrode is disposed on the exposed area of the first electrical connection layer, and the second electrode is disposed on the exposed area of the second electrical connection layer.

In an embodiment, the light emitting layer is disposed between the first electrode and the second electrode. That is, the light emitting layer exists between the first electrode and the second electrode.

In an embodiment, each of the plurality of wire bonding layers is across the light emitting layer of each of any two adjacent light emitting units.

In an embodiment, surfaces of the first electrode and the second electrode away from the substrate are lower than a surface of the epitaxial structure away from the substrate.

In an embodiment, the spacing between the two adjacent light emitting units is less than or equal to 30 μm.

In an embodiment, when the plurality of light emitting units are connected in series, the first electrode and the second electrode connected at two ends of the wire bonding layer are staggered.

In an embodiment, an optical power density of the light emitting device is greater than 3 W/mm².

The disclosure further provides a display device, which adopts the light emitting device described in any one of the above embodiments.

An advantage of the disclosure is to provide a light emitting device that can effectively reduce the spacing between the light emitting units and has high optical power density while ensuring the safe wire bonding distance through the disposition of the first electrode and/or the second electrode toward the middle of the light emitting unit; also, the overall size of the light emitting device can be reduced, which is beneficial for product usage.

### BENEFICIAL EFFECTS

Other features and beneficial effects of the disclosure will be described in the following description, and partly will become clear from the description, or will be understood by practicing the disclosure. The purpose and other beneficial effects of the disclosure can be achieved and obtained by the structures specifically pointed out in, for example, the specification and the appended claims.

### BRIEF DESCRIPTION OF THE DRAWINGS

In order to more clearly illustrate the embodiments of the disclosure or the technical solutions in the related art, the following briefly introduces the drawings required for use in the embodiments or the description of the related art. Certainly, the drawings described below are some embodiments of the disclosure. For ordinary technicians in this field, other drawings may be obtained based on the drawings without creative work. The positional relationships described in the drawings in the following description are based on the directions of the components shown in the drawings unless otherwise specified.

FIG. 1 is a schematic cross-sectional view of a light emitting device according to an embodiment of the disclosure.

FIG. 2 is a schematic structural top view of the light emitting device according to an embodiment of the disclosure.

FIG. 3 is a schematic structural top view of the light emitting device according to another embodiment of the disclosure.

FIG. 4 is a schematic structural top view of the light emitting device according to another embodiment of the disclosure.

FIG. 5 is a schematic structural top view of the light emitting device according to another embodiment of the disclosure.

FIG. 6 is a schematic structural top view of the light emitting device disposed on a circuit board according to another embodiment of the disclosure.

### REFERENCE NUMERALS

1, 2, 3, 4, 5—light emitting device; 10—light emitting unit; 12—substrate; 121—first side; 122—second side; 21—first electrode; 22—second electrode; 24—epitaxial structure; 241—first semiconductor layer; 242—light emitting layer; 243—second semiconductor layer; 26—groove; 28—insulation layer; 31—first electrical connection layer; 32—second electrical connection layer; 33—back electrode; 50—wire bonding layer; 70—circuit board; L1—first long side; B1—first short side; L2—second long side; B2—second short side; S1—wire bonding layer length; S2—spacing between two adjacent light emitting units; S3—length of the first long side; W1—first horizontal distance; W2—second horizontal distance; W3—third horizontal distance; W4—fourth horizontal distance; W5—fifth horizontal distance; H1—first vertical distance; H2—second vertical distance.

### DESCRIPTION OF THE EMBODIMENTS

In order to make the purpose, technical solution, and advantages of the embodiments of the disclosure clearer, the technical solution in the embodiments of the disclosure will be clearly and completely described below together with the drawings in the embodiments of the disclosure. Certainly, the described embodiments are part of the embodiments of the disclosure, not all of the embodiments; the technical features designed in different implementation manners of the disclosure described below may be combined with each other as long as the features do not conflict with each other; based on the embodiments of the disclosure, all other embodiments obtained by ordinary technicians in this field without making creative work are within the scope of protection of the disclosure.

In the description of the disclosure, it should be understood that the terms “center”,

“lateral”, “up”, “down”, “left”, “right”, “vertical”, “horizontal”, “top”, “bottom”, “inside”, “outside” and the like indicate positions or positional relationships based on the positions or positional relationships shown in the drawings, and are only for the convenience of describing the disclosure and simplifying the description, rather than indicating or implying that the device or component referred to has to have a specific orientation, or be constructed and operated in a specific orientation, and thus cannot be understood as limiting the disclosure. In addition, the terms “first” and “second” are only used for descriptive purposes, and cannot be understood as indicating or implying relative importance or implicitly indicating the quantity of technical features indicated. Therefore, the features defined as “first” and “second” may explicitly or implicitly include one or more of the features. In the description of the disclosure, unless otherwise specified, “multiple” means two or more. In addition, the term “includes” and any variation thereof all mean “at least includes”.

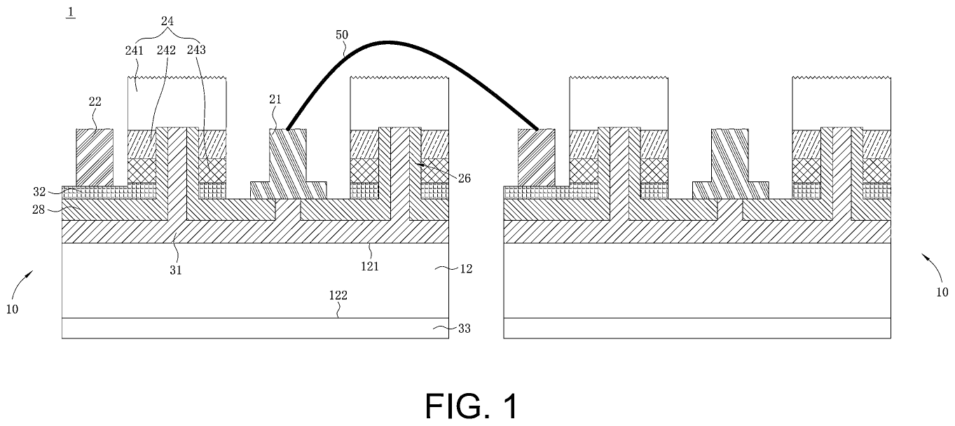

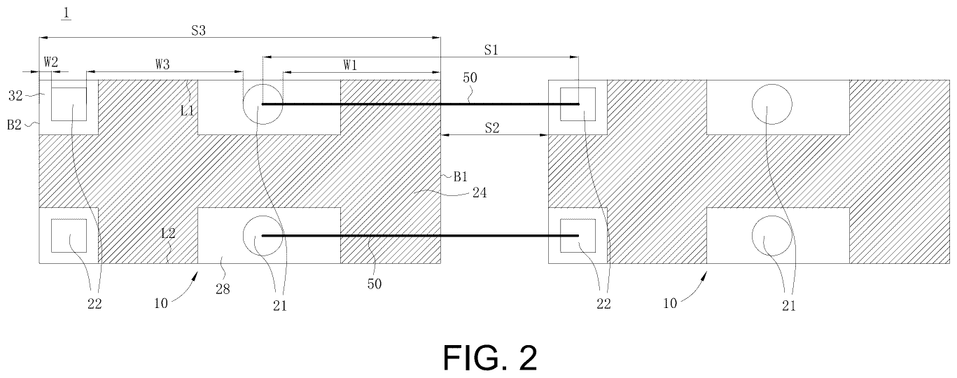

Please refer to FIG. 1 and FIG. 2. FIG. 1 is a schematic cross-sectional view of a light emitting device 1 according to an embodiment of the disclosure, and FIG. 2 is a schematic structural top view of the light emitting device 1 according to an embodiment of the disclosure. To achieve at least one of the above advantages or other advantages, an embodiment of the disclosure provides the light emitting device 1. As shown in the drawings, the light emitting device 1 includes a plurality of light emitting units 10 and a plurality of bonding wire layers 50.

Each light emitting unit 10 may include a substrate 12, a first electrode 21, and a second electrode 22. The substrate 12 has a first side 121 and a second side 122 opposite to each other. In FIG. 1, the first side 121 corresponds to the upper side, and the second side 122 corresponds to the lower side. Optionally, the substrate 12 is an insulating substrate, for example, the substrate 12 may be a patterned sapphire substrate.

The first electrode 21 and the second electrode 22 are located on the first side 121 of the substrate 12. The first electrode and the second electrode are spaced apart from each other, that is, the first electrode 21 and the second electrode 22 do not directly contact each other. The electrical properties of the first electrode and the second electrode are different, for example, the first electrode 21 and the second electrode 22 are respectively a positive electrode and a negative electrode, or respectively a negative electrode and a positive electrode. The first electrode 21 and the second electrode 22 may be a single-layer, a double-layer, or a multi-layer structure, which may include metals such as Ti, Al, Ni, Au, and Pt. The second electrode 22 may also be a transparent conductive layer (ITO).

The plurality of wire bonding layers 50 are used to electrically connect the plurality of light emitting units 10, for example, to connect the plurality of light emitting units 10 in series, in parallel, or in series-parallel mixed connection. In the embodiment, the plurality of wire bonding layers 50 connect the plurality of light emitting units 10 in series. Specifically, as shown in FIG. 1 and FIG. 2, an end of the wire bonding layer 50 is electrically connected to the first electrode 21 of one of two adjacent light emitting units 10, and another end of the wire bonding layer 50 is electrically connected to the second electrode 22 of the other of the two adjacent light emitting units 10. In the embodiment, a length S1 of each wire bonding layer 50 projected onto the light emitting unit 10 is greater than or equal to 150 μm to meet the requirements of the safe wire bonding distance; a spacing S2 between the two adjacent light emitting units 10 is 0.5 μm to 50 μm, that is, 0.5 μm≤S2≤50 μm, so as to effectively reduce the spacing S2 between the two adjacent light emitting units 10 while ensuring the wire bonding distance, so that the light emitting device 1 has high optical power density. The optical power density output by the light emitting device 1 can be greater than 3 W/mm², preferably greater than 4 W/mm², 5 W/mm², 6 W/mm²; also, the overall size of the light emitting device 1 can be reduced, which is beneficial for product usage. Preferably, the spacing S2 between the two adjacent light emitting units 10 can be less than or equal to 30 μm, 25 μm, or even 10 μm. In other embodiments, the optical power density output by the light emitting device can also be 2 W/mm².

The length S1 of the wire bonding layer 50 projected onto the light emitting unit 10 may be understood as the length of the wire bonding layer 50 projected onto the horizontal plane where the light emitting unit 10 is located, and may also be understood as that, when viewing from above the light emitting device toward the light emitting unit 10, the length of the wire bonding layer 50 is the length of the wire bonding layer 50 projected onto the light emitting unit 10. The spacing S2 between the two adjacent light emitting units 10 may be understood as the minimum spacing S2 between the two adjacent light emitting units 10, and when viewing from the top view FIG. 2, the distance from a first short side B1 of the light emitting unit 10 on the left side to the second short side B2 of the light emitting unit 10 on the right side is the spacing S2. The calculation formula of the optical power density is: optical power density=optical power/LED luminous area. The optical power may be measured using a standard optical measurement system, and then the optical power density is calculated.

In this embodiment, the quantity of the light emitting units 10 is two, and the two light emitting units 10 are connected in series through the wire bonding layer 50. Viewing from above the light emitting device 1 toward the light emitting unit 10, as shown in FIG. 2, each light emitting unit 10 has four sides. The four sides are defined as a first long side L1, a first short side B1, a second long side L2, and a second short side B2 sequentially in a surrounding direction. In this embodiment, the first electrode 21 is closer to the first short side B1 than the second electrode 22, and the second electrode 22 is closer to the second short side B2 than the first electrode 21. By shifting the first electrode 21 inward from the outer edge, the spacing S2 between the two adjacent light emitting units 10 is reduced while ensuring that the safe wire bonding distance remains unchanged. Specifically, a first horizontal distance W1 from the first electrode 21 to the first short side B1 is ⅛ to ½ of a length S3 of the first long side L1, and a second horizontal distance W2 from the second electrode 22 to the second short side B2 is 1/100 to 1/10 of the length S3 of the first long side L1, thereby reducing the spacing S2 between the two adjacent light emitting units 10. Optionally, the first horizontal distance W1 is 100 μm to 200 μm, thereby the spacing S2 between the two adjacent light emitting units 10 is reduced while ensuring that the safe wire bonding distance remains unchanged. In particular, when the size of the light emitting unit 10 is too large, the ratio of the first horizontal distance W1 to the length S3 becomes smaller, and at this time, the first horizontal distance W1 is 100 μm to 200 μm, which can effectively reduce the spacing S2 between the two adjacent light emitting units 10.

In an embodiment, there is a third horizontal distance W3 between the first electrode 21 and the second electrode 22 of each light emitting unit 10, the third horizontal distance W3 is 3/10 to ½ of the length S3 of the first long side L1 to prevent the first electrode 21 and the second electrode 22 from being too close to each other and causing risks such as short circuit.

In an embodiment, considering that the conventional diode structure is highly dependent on the electrode position in order to ensure good electrical characteristics and light emission characteristics, it is not easy to change the electrode position. Therefore, a diode structure with low dependence on the electrode position is provided, which does not need to consider the position of the current injection point to avoid the current congestion effect. As shown in FIG. 1, the light emitting unit 10 further includes an epitaxial structure 24, a groove 26, and an insulation layer 28.

The epitaxial structure 24 includes a first semiconductor layer 241, a light emitting layer 242, and a second semiconductor layer 243. The light emitting layer 242 is located between the first semiconductor layer 241 and the second semiconductor layer 243, and the second semiconductor layer 243 is closer to the substrate 12 than the first semiconductor layer 241.

The first semiconductor layer 241 may be an N-type semiconductor layer, which may provide electrons to the light emitting layer 242 under the action of a power source. In some embodiments, the first semiconductor layer 241 includes an N-type doped nitride layer. The N-type doped nitride layer may include one or more N-type impurities of group IV elements. The N-type impurities may include one or a combination of Si, Ge, Sn.

The light emitting layer 242 may be a quantum well (QW) structure. In some embodiments, the light emitting layer 242 may also be a multiple quantum well (MQW) structure, in which the multiple quantum well structure includes multiple quantum wells and multiple quantum barriers alternately arranged in a repeated manner, for example, the arrangement may be a multiple quantum well structure of GaN/AlGaN, InAlGaN/InAlGaN, or InGaN/AlGaN. In addition, the composition and thickness of the well in the light emitting layer 242 determine the wavelength of the generated light. In order to improve the luminous efficiency of the light emitting layer 242, the purpose can be achieved by changing the depth of the quantum well, the quantity of layers, thickness and/or other characteristics of the paired quantum wells and quantum barriers in the light emitting layer 242.

The second semiconductor layer 243 may be a P-type semiconductor layer, which may provide holes to the light emitting layer 242 under the action of a power source. In some embodiments, the second semiconductor layer 243 includes a P-type doped nitride layer. The P-type doped nitride layer may include one or more P-type impurities of group II elements. The P-type impurities may include one or a combination of Mg, Zn, and Be. The second semiconductor layer 243 may be a single-layer structure or a multi-layer structure, and the multi-layer structure has different compositions. In addition, the configuration of the epitaxial structure 24 is not limited to the above description, and other types of epitaxial structures 24 may be selected according to actual needs.

The groove 26 extends to the first semiconductor layer 241 in a direction from the surface

(lower surface) of the second semiconductor layer 243 toward the light emitting layer 242 to expose a portion of the first semiconductor layer 241, so as to facilitate the first electrode 21 being electrically connected to the first semiconductor layer 241. Specifically, the first electrode 21 is electrically connected to the first semiconductor layer 241, and the second electrode 22 is electrically connected to the second semiconductor layer 243.

The insulation layer 28 covers the groove 26 and the epitaxial structure 24 so that the first electrode 21 and the second electrode 22 are electrically insulated from each other. Preferably, the insulation layer 28 covers the sidewall and part of the bottom of the groove 26 and the lower surface of the second semiconductor layer 243. The material of the insulation layer 28 includes a non-conductive material. The non-conductive material is preferably an inorganic material or a dielectric material. The inorganic material may include silicone. The dielectric material includes an electrically insulating material such as aluminum oxide (AlO), silicon nitride (SiNx), silicon oxide (SiOx), titanium oxide (TiOx), or magnesium fluoride (MgFx). For example, the insulation layer 28 may be a single-layer structure of silicon dioxide, silicon nitride, titanium oxide, tantalum oxide, niobium oxide, barium titanate, or a multi-layer structure formed by a combination thereof, and the combination thereof may be, for example, a Bragg reflector (DBR) formed by repeated stacking of two materials. That is, the insulation layer 28 may be a DBR reflective insulation layer.

Each light emitting unit 10 further includes a first electrical connection layer 31 and a second electrical connection layer 32. The first electrical connection layer 31 and the second electrical connection layer 32 are electrically insulated from each other through the insulation layer 28. The first electrical connection layer 31 is connected to the first semiconductor layer 241 through the groove 26. Preferably, the first electrical connection layer 31 is entirely covered on the surface of the first side 121 of the substrate 12. The second electrical connection layer 32 is connected to the second semiconductor layer 243. Preferably, the second electrical connection layer 32 completely covers the lower surface of the second semiconductor layer 243 (the surface of the second semiconductor of the side close to the substrate 12), and is disposed on the insulation layer 28. The first electrical connection layer 31 and the second electrical connection layer 32 have an exposed area at a side away from the substrate 12, that is, part of the upper surface of the first electrical connection layer 31 is exposed, and part of the upper surface of the second electrical connection layer 32 is exposed. The first electrode 21 is disposed on the exposed area of the first electrical connection layer 31, which is electrically connected to the first semiconductor layer 241 through the first electrical connection layer 31. The second electrode 22 is disposed on the exposed area of the second electrical connection layer 32, which is electrically connected to the second semiconductor layer 243 through the second electrical connection layer 32.

Specifically, since the second electrode 22 is electrically conducted to the second semiconductor layer 243 by the second electrical connection layer 32 disposed almost entirely below the epitaxial structure 24, the second electrode 22 has almost the same effect wherever it is placed on the second electrical connection layer 32 (the second electrode 22 conducts current by the entire second electrical connection layer 32); similarly, the first electrode 21 is also electrically conducted to the first semiconductor layer 241 by the first electrical connection layer 31 disposed almost entirely below, so the first electrode 21 has almost the same effect wherever the electrode is placed on the first electrical connection layer 31 (the first electrode 21 conducts current by the entire first electrical connection layer 31). In the configuration, the exposed areas of the first electrical connection layer 31 and the second electrical connection layer 32 may be adaptively adjusted.

The light emitting layer 242 is disposed between the first electrode 21 and the second electrode 22, that is, the light emitting layer 242 exists between the first electrode 21 and the second electrode 22, and the shaded portion in FIG. 2 is the area where the light emitting layer 242 is located. In other words, the light emitting layer 242 exists between the lateral ranges of the first electrode 21 and the second electrode 22. Preferably, the light emitting layer 242 exists around the first electrode 21 and around the second electrode 22 to effectively reduce the spacing S2 between two adjacent light emitting units 10. The wire bonding layer 50 is across the light emitting layer 242 of one of the two adjacent light emitting units 10. The surfaces of the first electrode 21 and the second electrode 22 away from the substrate 12 are lower than the surface of the epitaxial structure 24 away from the substrate 12, that is, the upper surfaces of the first electrode 21 and the second electrode 22 in FIG. 1 are lower than the upper surface of the epitaxial structure 24, and the first electrode 21 and the second electrode 22 are distributed inside the epitaxial structure 24 to improve the electrical characteristics of the light emitting device 1 and facilitate the layout and use of the wire bonding layer 50.

The light emitting unit 10 may further include a back electrode 33. The back electrode 33 is disposed on the surface of the second side 122 of the substrate 12 for subsequent die bonding, which is beneficial for the subsequent mounting of the light emitting device 1 on a circuit board.

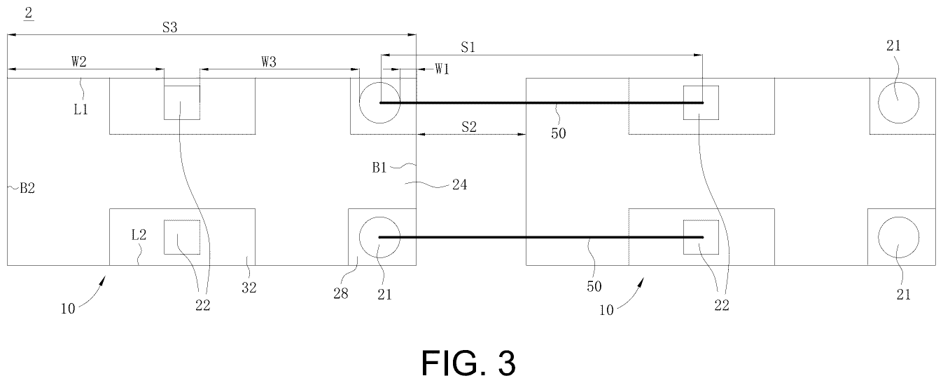

Please refer to FIG. 3. FIG. 3 is a schematic structural top view of a light emitting device 2 according to another embodiment of the disclosure. To achieve at least one of the above advantages or other advantages, an embodiment of the disclosure provides the light emitting device 2. As shown in the drawing, comparing the light emitting device 2 of this embodiment with the light emitting device 1 shown in FIG. 1 and FIG. 2, the main difference is that the second electrode 22 is shifted inward to reduce the spacing S2 between two adjacent light emitting units, and the rest of similar contents will not be repeated in detail. Specifically, the second horizontal distance W2 from the second electrode 22 to the second short side B2 is ⅛ to ½ of the length S3 of the first long side L1, and at this time, the first horizontal distance W1 from the first electrode 21 to the first short side B1 is 1/100 to 1/10 of the length S3 of the first long side L1. Optionally, the second horizontal distance W2 is 100 μm to 200 μm, so as to reduce the spacing S2 between two adjacent light emitting units 10 while ensuring that the safe wire bonding distance remains unchanged. In particular, when the size of the light emitting unit 10 is too large, the ratio of the second horizontal distance W2 to the length S3 becomes smaller, and at this time, the second horizontal distance W2 is 100 μm to 200 μm, which can effectively reduce the spacing S2 between the two adjacent light emitting units 10.

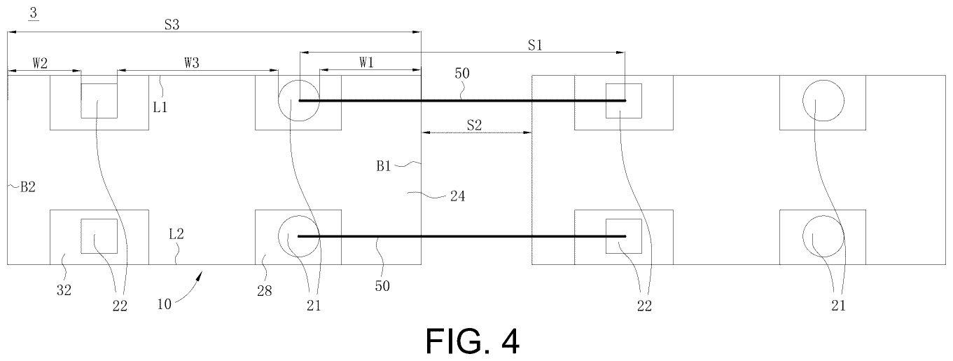

Please refer to FIG. 4. FIG. 4 is a schematic structural top view of a light emitting device 3 according to another embodiment of the disclosure. To achieve at least one of the above advantages or other advantages, an embodiment of the disclosure provides the light emitting device 3. As shown in the drawing, comparing the light emitting device 3 of this embodiment with the light emitting device 1 shown in FIG. 1 and FIG. 2, the main difference is that the first electrode 21 and the second electrode 22 are simultaneously shifted inward to reduce the spacing S2 between two adjacent light emitting units 10, and the rest of similar contents will not be repeated in detail. Specifically, the first horizontal distance W1 from the first electrode 21 to the first short side B1 is 1/16 to ⅛ of the length S3 of the first long side L1, and the second horizontal distance W2 from the second electrode 22 to the second short side B2 is 1/16 to ⅛ of the length S3 of the first long side L1.

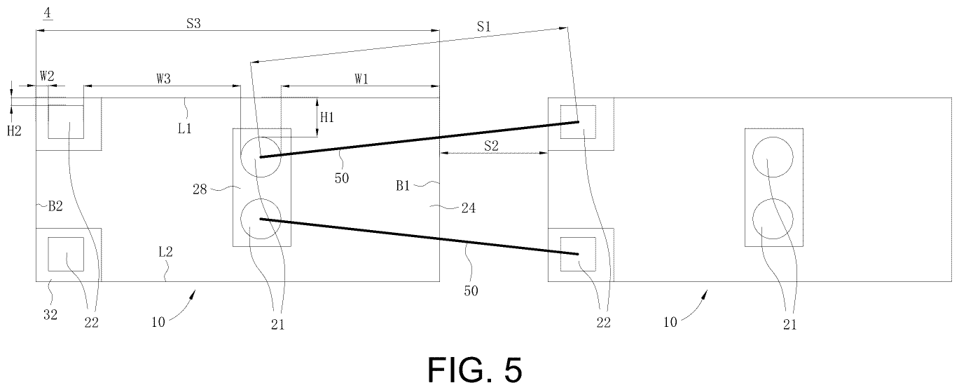

Please refer to FIG. 5. FIG. 5 is a schematic structural top view of a light emitting device 4 according to another embodiment of the disclosure. To achieve at least one of the above advantages or other advantages, an embodiment of the disclosure provides the light emitting device 4. As shown in the drawing, comparing the light emitting device 4 of this embodiment with the light emitting device 1 shown in FIG. 1 and FIG. 2, the main difference (the similar contents will not be repeated) is that the electrodes connected at the two ends of the wire bonding layer 50 are staggered. The drawing shows that when connected in series, the first electrode 21 and the second electrode 22 connected to the two ends of the wire bonding layer 50 are staggered. When viewing from a top view, the first electrode 21 and the second electrode 22 connected to the two ends of the wire bonding layer 50 are no longer on the same horizontal line, but are staggered up and down, so that the wire bonding layer 50 is disposed obliquely (viewing from a top view). Optionally, a first vertical distance H1 from the first electrode 21 to the first long side L1 is 3/20 to 3/10 of a length of a first short side B1, a second vertical distance H2 from the second electrode 22 to the first long side L1 is 1/50 to 1/20 of the length of the first short side B1, and the first vertical distance H1 is greater than the second vertical distance H2. Optionally, the first vertical distance H1 from the first electrode 21 to the first long side L1 is 1/50 to 1/20 of the length of the first short side B1, the second vertical distance H2 from the second electrode 22 to the first long side L1 is 3/20 to 3/10 of the length of the first short side B1, and the second vertical distance H2 is greater than the first vertical distance H1. With this arrangement, the spacing S2 between two adjacent light emitting units 10 can be further reduced while ensuring the safe wire bonding distance, and the rest of similar contents will not be repeated in detail. Similarly, the positions of the first electrode 21 and the second electrode 22 connected by the wire bonding layer 50 in FIG. 3 and FIG. 4 may be changed so that the first electrode 21 and the second electrode 22 are staggered, so that the wire bonding layer 50 is arranged obliquely, so as to further reduce the spacing S2 between two adjacent light emitting units 10.

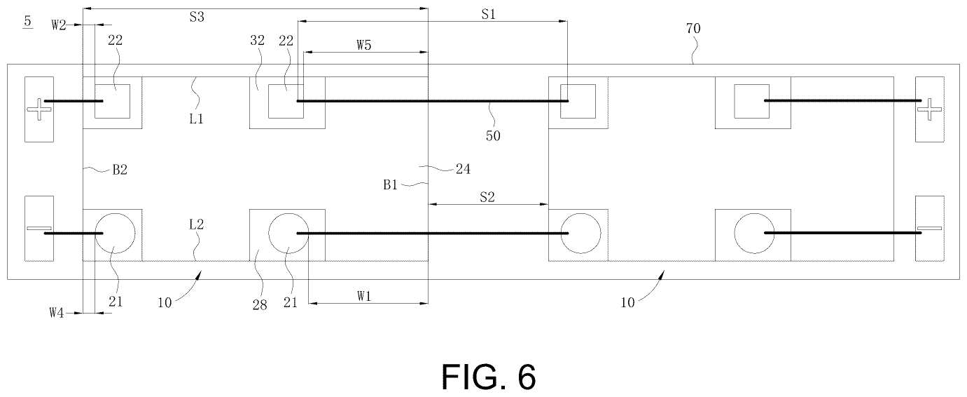

Please refer to FIG. 6. FIG. 6 is a schematic structural top view of a light emitting device 5 disposed on a circuit board 70 according to another embodiment of the disclosure. To achieve at least one of the above advantages or other advantages, an embodiment of the disclosure provides the light emitting device 5. As shown in the drawing, comparing the light emitting device 5 of this embodiment with the light emitting device 1 shown in FIG. 1 and FIG. 2, the main difference (the similar contents will not be repeated) is that the plurality of light emitting units 10 in this embodiment are connected in parallel, the first horizontal distance W1 from the first electrode 21 to the first short side B1 is ⅛ to ½ of the length S3 of the first long side L1, the fifth horizontal distance W5 from the second electrode 22 to the first short side B1 is also ⅛ to ½ of the length S3 of the first long side L1, and at this time, the second horizontal distance W2 from the second electrode 22 to the second short side B2 is 1/100 to 1/10 of the length S3 of the first long side L1, and the fourth horizontal distance W4 from the first electrode 21 to the second short side B2 is also 1/100 to 1/10 of the length S3 of the first long side L1, thereby reducing the spacing S2 between the two adjacent light emitting units 10.

Similarly, when the series-type light emitting devices shown in FIG. 3, FIG. 4, and FIG. 5 are replaced with parallel-type light emitting devices, the relationship between the various distances are adjusted in different adaptive ways. For example: the first horizontal distance W1 from the first electrode 21 to the first short side B1 is 1/100 to 1/10 of the length S3 of the first long side L1, the fourth horizontal distance W4 from the first electrode 21 to the second short side B2 is ⅛ to ½ of the length S3 of the first long side L1, the second horizontal distance W2 from the second electrode 22 to the second short side B2 is 1/100 to 1/10 of the length S3 of the first long side L1, and the fifth horizontal distance W5 from the second electrode 22 to the first short side B1 is ⅛ to ½ of the length S3 of the first long side L1; or, the first horizontal distance W1 from the first electrode 21 to the first short side B1 is 1/16 to ⅛ of the length S3 of the first long side L1, the fourth horizontal distance W4 from the first electrode 21 to the second short side B2 is 1/16 to ⅛ of the length S3 of the first long side L1, the second horizontal distance W2 from the second electrode 22 to the second short side B2 is 1/16 to ⅛ of the length S3 of the first long side L1, and the fifth horizontal distance W5 from the second electrode 22 to the first short side B1 is 1/16 to ⅛ of the length S3 of the first long side L1.

In addition, the light emitting device 5 is disposed on the circuit board 70, and the light emitting device 5 is electrically connected to the positive electrode and the negative electrode on the circuit board 70.

It should be noted that the first horizontal distance W1, the second horizontal distance W2, the third horizontal distance W3, the fourth horizontal distance W4, the fifth horizontal distance W5, the first vertical distance H1, and the second vertical distance H2 all refer to the minimum distances when viewing from a top view. Taking FIG. 2 as an example, the first horizontal distance W1 is the minimum distance from the first electrode 21 to the first short side B1, that is, the vertical distance from the right end point of the first electrode 21 to the first short side B1 in the example.

The wire bonding layer 50 may electrically connect the plurality of light emitting units 10 through methods such as coating or wire bonding. The wire bonding layer 50 may be a transparent wire bonding layer or a metal wire bonding layer. In practice, a transparent wire bonding layer is easier to form, which allows the spacing S2 between two adjacent light emitting units 10 to be smaller, such as less than or equal to 5 μm.

An embodiment of the disclosure further provides a display device, which includes the light emitting device 1, 2, 3, 4, and 5 described in any of the above embodiments, and the specific structures and technical effects will not be repeated.

In summary, the disclosure provides the light emitting device 1, 2, 3, 4, and 5, through the first electrode 21 and/or the second electrode 22. Through the disposition of the first electrode 21 and/or the second electrode 22 toward the middle of the light emitting unit 10, the spacing between the light emitting units 10 can be effectively reduced while ensuring the safe wire bonding distance, so that the light emitting devices 1, 2, 3, 4, and 5 have high optical power density; also, the overall size of the light emitting devices 1, 2, 3, 4, and 5 can also be reduced, which is beneficial for product usage.

In addition, the value range of “to” mentioned above includes the two endpoint values, which are all within the protection scope of the disclosure. Persons skilled in the art should understand that although there are many problems in the related, each embodiment or technical solution of the disclosure can be improved in only one or several aspects, without having to solve all the technical problems listed in the related art or background technology at the same time. Person skilled in the art should understand that the content not mentioned in a claim should not be used as a limitation to the claim.

Finally, it should be noted that the above embodiments are only used to illustrate the technical solutions of the disclosure, rather than to limit the disclosure. Although the disclosure has been described in detail with reference to the above embodiments, persons skilled in the art should understand that the technical solutions described in the above embodiments may still be modified, or some or all of the technical features may be replaced by equivalents. However, the modifications or replacements do not deviate the essence of the corresponding technical solutions from the scope of the technical solutions of the embodiments of the disclosure.

What is claimed is:

1. A light emitting device, comprising:
a plurality of light emitting units, wherein each of the plurality of light emitting units comprises a first electrode and a second electrode, the first electrode and the second electrode are spaced apart from each other, and electrical properties of the first electrode and the second electrode are different;
a plurality of wire bonding layers, wherein the plurality of light emitting units are electrically connected to each other through the plurality of wire bonding layers,
wherein a spacing between two adjacent light emitting units is 0.5 μm to 50 μm, and a length of each of the plurality of wire bonding layers projected onto one of the light emitting units is greater than or equal to 150 μm.

2. The light emitting device according to claim 1, wherein
the plurality of light emitting units are connected in series, viewing from above the light emitting device toward the plurality of light emitting units, each of the plurality of light emitting units has four sides, and the four sides are defined as a first long side, a first short side, a second long side, and a second short side sequentially in a surrounding direction,
wherein a first horizontal distance from the first electrode to the first short side is ⅛ to ½ of a length of the first long side, and a second horizontal distance from the second electrode to the second short side is 1/100 to 1/10 of the length of the first long side,
or the second horizontal distance from the second electrode to the second short side is ⅛ to ½ of the length of the first long side, and the first horizontal distance from the first electrode to the first short side is 1/100 to 1/10 of the length of the first long side,
or the first horizontal distance from the first electrode to the first short side is 1/16 to ⅛ of the length of the first long side, and the second horizontal distance from the second electrode to the second short side is 1/16 to ⅛ of the length of the first long side.

3. The light emitting device according to claim 1, wherein
the plurality of light emitting units are connected in parallel, viewing from above the light emitting device toward the plurality of light emitting units, each of the plurality of light emitting units has four sides, and the four sides are defined as a first long side, a first short side, a second long side, and a second short side sequentially in a surrounding direction,
wherein a first horizontal distance from the first electrode to the first short side is ⅛ to ½ of a length of the first long side, a fourth horizontal distance from the first electrode to the second short side is 1/100 to 1/10 of the length of the first long side, a second horizontal distance from the second electrode to the second short side is ⅛ to ½ of the length of the first long side, and a fifth horizontal distance from the second electrode to the first short side is 1/100 to 1/10 of the length of the first long side,
or the first horizontal distance from the first electrode to the first short side is 1/100 to 1/10 of the length of the first long side, the fourth horizontal distance from the first electrode to the second short side is ⅛ to ½ of the length of the first long side, the second horizontal distance from the second electrode to the second short side is 1/100 to 1/10 of the length of the first long side, and the fifth horizontal distance from the second electrode to the first short side is ⅛ to ½ of the length of the first long side,
or the first horizontal distance from the first electrode to the first short side is 1/16 to ⅛ of the length of the first long side, the fourth horizontal distance from the first electrode to the second short side is 1/16 to ⅛ of the length of the first long side, the second horizontal distance from the second electrode to the second short side is 1/16 to ⅛ of the length of the first long side, and the fifth horizontal distance from the second electrode to the first short side is 1/16 to ⅛ of the length of the first long side.

4. The light emitting device according to claim 2, wherein
a first vertical distance from the first electrode to the first long side is 3/20 to 3/10 of a length of a first short side, a second vertical distance from the second electrode to the first long side is 1/50 to 1/20 of the length of the first short side, and the first vertical distance is greater than the second vertical distance,
or the first vertical distance from the first electrode to the first long side is 1/50 to 1/20 of the length of the first short side, the second vertical distance from the second electrode to the first long side is 3/20 to 3/10 of the length of the first short side, and the first vertical distance is less than the second vertical distance.

5. The light emitting device according to claim 2, wherein there is a third horizontal distance between the first electrode and the second electrode of each of the plurality of light emitting units, and the third horizontal distance is 3/10 to ½ of the length of the first long side.

6. The light emitting device according to claim 1, wherein each of the plurality of light emitting units further comprises a substrate, the substrate has a first side and a second side opposite to each other, and the first electrode and the second electrode are located on the first side of the substrate.

7. The light emitting device according to claim 6, wherein each of the plurality of light emitting units further comprises an epitaxial structure, a groove, and an insulation layer, the epitaxial structure comprises a first semiconductor layer, a light emitting layer, and a second semiconductor layer, the light emitting layer is located between the first semiconductor layer and the second semiconductor layer, the second semiconductor layer is closer to the substrate than the first semiconductor layer, the groove extends to the first semiconductor layer in a direction from a surface of the second semiconductor layer to the light emitting layer, the first electrode is electrically connected to the first semiconductor layer, the second electrode is electrically connected to the second semiconductor layer, and the insulation layer covers the groove and the epitaxial structure, so that the first electrode and the second electrode are electrically insulated from each other.

8. The light emitting device according to claim 7, wherein each of the plurality of light emitting units further comprises a first electrical connection layer and a second electrical connection layer, the first electrical connection layer is connected to the first semiconductor layer through the groove, the second electrical connection layer is connected to the second semiconductor layer, the first electrical connection layer and the second electrical connection layer each have an exposed area at a side away from the substrate, the first electrode is disposed on the exposed area of the first electrical connection layer, and the second electrode is disposed on the exposed area of the second electrical connection layer.

9. The light emitting device according to claim 8, wherein the light emitting layer is disposed between the first electrode and the second electrode.

10. The light emitting device according to claim 7, wherein each of the plurality of wire bonding layers is across the light emitting layer of each of any two adjacent light emitting units.

11. The light emitting device according to claim 7, wherein surfaces of the first electrode and the second electrode away from the substrate are lower than a surface of the epitaxial structure away from the substrate.

12. The light emitting device according to claim 1, wherein the spacing between the two adjacent light emitting units is less than or equal to 30 μm.

13. The light emitting device according to claim 1, wherein an optical power density of the light emitting device is greater than 3 W/mm².
